(19) United States
(12) Patent Application Publication
(10) Pub. No.: US 2026/0219304 A1
(43) Pub. Date: Jul. 30, 2026

(54) METHODS, APPARATUSES, CIRCUITS AND DEVICES FOR PROVIDING SENSING FEEDBACK FOR SYSTEMS EMPLOYING SPECTRUM FUSION

(71) Applicant: Huawei Technologies Co., Ltd., Shaenzhen (CN)

(72) Inventors: Ahmed Wagdy Shaban, Ottawa (CA); Alireza Bayesteh, Brossard (CA); Jianglei Ma, Ottawa (CA)

(21) Appl. No.: 19/573,327

(22) Filed: Mar. 20, 2026

Related U.S. Application Data
(63) Continuation of application No. PCT/CN2024/091444, filed on Jun. 29, 2024.
(60) Provisional application No. 63/585,398, filed on Sep. 26, 2023.

(51) Int. Cl. G01R 21/133

(52) U.S. Cl. CPC G01R 21/133

(57) ABSTRACT

A method includes receiving first parameters and second parameters, receiving a sensing signal, projecting the sensing signal over a domain to perform two or more measurements according to the first parameters, generating a signal from the two or more measurements according to the second parameters, the signal comprising two or more spectrally fusible measurements over two or more frequencies, and transmitting the signal. The method may also include transmitting a spectrum fusion capability report. The two or more measurements may be embedded in the signal, may include measuring average power for different frequency bandwidths and spectrum fusion carrier phase measurements. The second parameters may be for uniform sampling using a configured sampling frequency, non-uniform sampling with a configured sampling frequency, for measuring amplitude of samples, for measuring real and imaginary components of samples, for pre-configured quantization, or may include cut-off thresholds.

### CROSS-REFERENCE TO RELATED APPLICATION

The present application is a continuation of International Patent Application PCT/CN2024/091444, filed on Jun. 29, 2024, which claims the benefit of U.S. Patent Application No. 63/585,398, filed on Sep. 26, 2023. The entire contents of these applications are hereby incorporated by reference.

### TECHNICAL FIELD

The present disclosure relates generally to sensing in wireless systems, and in particular to methods, apparatuses, circuits, and devices for providing sensing feedback for sensing systems employing spectrum fusion.

### BACKGROUND

Sensing information of user equipment (UE) may be used in communication networks, including for cellular or wireless communication networks, for improving performance of a network according to certain performance metrics. Such performance metrics may, for example, include capacity, agility, and efficiency of the network. Improvements may be achieved when elements of the network make use of the position, the behavior, the mobility pattern, etc., of UE in the context of a priori information describing a wireless environment in which the UE may be operating.

Sensing systems may be used for gathering UE sensing information, including location of devices, such as relative to a global coordinate system, velocity and direction of movement of devices in a global coordinate system, orientation information of devices, and the information about wireless environments. While a sensing system may be independently from a communication system, there may be advantages to operating an integrated to gather and share information, reducing required resources, such as hardware, including associated costs, for the system as well as providing operational efficiencies, such as reduced operation or processing time, increasing frequency, or reducing required spatial resources for meeting requirement of both sensing and communications systems. However, the use communication system hardware in UE to perform sensing functions relating to position and environmental information may result in challenges and introduce issues. The challenges and issues may be related to a variety of factors such as limited resolution of a communication system, dynamic natures of environments, and potentially large number of objects whose electromagnetic properties and positions that are to be estimated.

As a result, efficient and effective integrated sensing and communication systems, which may also be referred to as integrated communication and sensing systems, joint sensing and communication systems, and/or the like may be desirable for a variety of applications for existing and future communication systems.

### SUMMARY

Embodiments disclosed herein relate to apparatuses, circuits, devices and methods wherein a signal comprising multiple fusible measurements over multiple frequencies may be generated and transmitted, which may be fused at another node, such as a fusion node. Two or more measurements may be generated projecting a sensing signal over a domain to perform one or more measurements according to a first set of parameters. The signal may be generated according to a second set of parameters.

In a broad aspect according to embodiments of the present disclosure, a method comprises: receiving first parameters and second parameters; receiving a sensing signal; projecting the sensing signal over a domain to perform two or more measurements according to the first parameters; generating a signal from the two or more measurements according to the second parameters, the signal comprising two or more spectrally fusible measurements over two or more frequencies; and transmitting the signal.

In some embodiments, the method further comprises transmitting a spectrum fusion capability report.

In some embodiments, the two or more measurements are embedded in the signal.

In some embodiments, the two or more measurements comprises measuring average power for different frequency bandwidths.

In some embodiments, the two or more measurements comprise spectrum fusion carrier phase measurements.

In some embodiments, the second parameters comprise parameters for uniform sampling using a configured sampling frequency.

In some embodiments, the second parameters comprise parameters for non-uniform sampling with a configured sampling frequency

In some embodiments, the second parameters comprise parameters for measuring amplitude of samples.

In some embodiments, the second parameters comprise parameters for measuring real and imaginary components of samples.

In some embodiments, the second parameters are for pre-configured quantization.

In some embodiments, the second parameters comprise cut-off thresholds.

In some embodiments, the sensing signal is received over a sub-band.

In some embodiments, the sensing signal is received two or more sub-bands.

In some embodiments, the method further comprises modulating the two or more measurements to a modulated signal and transmitting the modulated signal.

In a broad aspect according to embodiments of the present disclosure, a method comprises: transmitting first parameters and second parameters; transmitting a sensing signal; and receiving a signal, the signal generated from two or more measurements performed according to the first parameters and generated according to the second parameters, the signal comprising two or more spectrally fusible measurements over two or more frequencies.

In some embodiments, the method comprises receiving a spectrum fusion capability report.

In some embodiments, the two or more spectrally fusible measurements are embedded in the signal.

In some embodiments, the two or more measurements comprise average power for different frequency bandwidth.

In some embodiments, the two or more measurements comprise spectrum fusion carrier phase measurements.

In some embodiments, the second parameters comprise parameters for uniform sampling using a configured sampling frequency.

In some embodiments, the second parameters comprise parameters for non-uniform sampling using a configured sampling frequency.

In some embodiments, the second parameters comprise parameters for measuring amplitude of samples.

In some embodiments, the second parameters comprise parameters for measuring real and imaginary components of samples.

In some embodiments, the second parameters are for pre-configured quantization.

In some embodiments, the second parameters comprise cut off thresholds.

In some embodiments, the sensing signal is transmitted over a sub-band.

In some embodiments, the sensing signal is transmitted two or more sub-bands.

In some embodiments, the method further comprises receiving a modulated signal, the modulated signal a modulation of two or more measurements.

In some embodiments, an apparatus comprises: a transmitter for transmitting; a receiver for receiving; a memory for storing instructions; and a processor for causing the apparatus to perform the method.

In some embodiments, one or more circuits of an apparatus, the one or more circuits for causing the apparatus to perform the method.

In some embodiments, one or more non transitory computer readable storage devices comprising instructions which, when the program is executed by a computer, cause the device to perform the method.

### BRIEF DESCRIPTION OF THE DRAWINGS

For a more complete understanding of the disclosure, reference is made to the following description and accompanying drawings, in which:

FIG. 1 is a schematic diagram illustrating a communication system according to some embodiments of the present disclosure;

FIG. 2 is a schematic diagram illustrating a communication system according to some embodiments of the present disclosure;

FIG. 3 is a schematic diagram of an electronic device and a base station according to some embodiments of the present disclosure;

FIG. 4 is a schematic diagram of modules of an electronic device according to some embodiments of the present disclosure;

FIG. 5 is a graph illustrating a graph of the quantization of |β₂w₂| according to some embodiments of the present disclosure;

FIG. 6 is a schematic diagram of the modulated and unmodulated parts of a sensing signal according to some embodiments of the present disclosure;

FIG. 7 is a signal flow diagram according to some embodiments of the present disclosure;

FIG. 8 is block diagram of a method according to some embodiments of this disclosure; and

FIG. 9 is block diagram of a method according to some embodiments of this disclosure.

### DETAILED DESCRIPTION OF THE ILLUSTRATIVE EMBODIMENTS

Unless otherwise defined, all technical and scientific terms used herein generally have the same meaning as commonly understood by one of ordinary skill in the art to which this disclosure pertains. Exemplary terms are defined below for ease in understanding the subject matter of the present disclosure.

The term “a” or “an” refers to one or more of that entity; for example, “a module” refers to one or more modules or at least one module. As such, the terms “a” (or “an”), “one or more” and “at least one” are used interchangeably herein. In addition, reference to an element or feature by the indefinite article “a” or “an” does not exclude the possibility that more than one of the elements or features are present, unless the context clearly requires that there is one and only one of the elements. Furthermore, reference to a feature in the plurality (e.g., modules), unless clearly intended, does not mean that the modules or methods disclosed herein must comprise a plurality.

The expression “and/or” refers to and encompasses any and all possible combinations of one or more of the associated listed items (e.g. one or the other, or both), as well as the lack of combinations when interrupted in the alternative (or).

Sensing information of user equipment (UE) may be used in communication networks, including for cellular or wireless communication networks, for improving performance of a network according to certain performance metrics. Such performance metrics may, for example, include capacity, agility, and efficiency of the network. Improvements may be achieved when elements of the network make use of the position, the behavior, the mobility pattern, etc., of UE in the context of a priori information describing a wireless environment in which the UE may be operating. Sensing information may comprise position information, velocity and heading information and orientation information.

Sensing systems may be used for gathering UE positional information, including location of devices, such as relative to a global coordinate system, velocity and direction of movement of devices in a global coordinate system, orientation information of devices, and the information about wireless environments. The term “location” as used herein may also refer to “position”, and these two terms may be used interchangeably herein. Examples of well-known sensing systems include radio detection and ranging (RADAR) and light detection and ranging (LIDAR). While a sensing system may be independently from a communication system, there may be advantages to operating an integrated to gather and share information, reducing required resources, such as hardware, including associated costs, for the system as well as providing operational efficiencies, such as reduced operation or processing time, increasing frequency, or reducing required spatial resources for meeting requirement of both sensing and communications systems. However, the use of communication system hardware in UE to perform sensing functions relating to position and environmental information may result in challenges and introduce issues. The challenges and issues may be related to a variety of factors such as limited resolution of a communication system, dynamic natures of environments, and potentially large number of objects whose electromagnetic properties and positions that are to be estimated.

As a result, efficient and effective integrated sensing and communication systems, which may also be referred to as integrated communication and sensing systems, joint sensing and communication systems, and/or the like may be desirable for a variety of applications for existing and future communication systems.

Nodes and terminals for some future wireless networks and systems (such as beyond 5G and 6G systems) may be expected to be suitable for dual functionality, namely communication and sensing, simultaneously while maintaining high spectral efficiency. Moreover, many future applications and use-cases for these systems may require precise sensing accuracy and high communication data rates. This may require allocating large amounts of bandwidth at each node and terminal to accommodate both functionalities and to achieve required sensing accuracy and communication data rates. However, allocating large amounts of bandwidth at each node and terminal may not be suitable for some network applications as a result of spectrum scarcity, and large numbers of nodes, terminals and users in such an application. Moreover, transmitting, receiving and processing ultra-wide bandwidth sensing signals may only be afforded to a limited number of terminals and/or UEs due to limited power and limited hardware bandwidth requirements and diminished processing capabilities. Future wireless communication systems may be designed to address these issues to provide network-wide high-resolution sensing information in future wireless systems.

Spectrum fusion, also known as bandwidth or multi-band splicing, frequency carriers or layers fusion, may be used to fuse multiple measurements performed over a plurality of frequency carriers, such as low-bandwidth frequency carriers or frequency bands, for increasing the total effective bandwidth used for measurements. Note that the terms frequency carrier, frequency layer, frequency band, and frequency sub-band may be used interchangeably herein, wherein a portion of a resource may be defined in the frequency domain over which a sensing signal is transmitted and measured. Fusing multiple low-bandwidth measurements for a plurality of non-overlapping low-bandwidth frequency carriers may provide high sensing resolution and/or accuracy gains compared to performance improvements associated with utilizing one ultra-high bandwidth sensing signal. However, spectrum fusion may require complex signal processing at a fusing node, which may not be feasible with some terminals and/or UEs. This may especially be relevant where terminals and/or UEs operate in low power modes or are under reduced capabilities constraints. Such terminals and/or UEs, that are performing multiple sensing measurements over a plurality of low-bandwidth frequency carriers, may not be capable of properly fusing these measurements to obtain the of interest high resolution and/or accuracy sensing parameters. As a result, these terminals and/or UEs may instead of processing the measurements, collected over a plurality of low-bandwidth frequency carriers, and fusing them, transmit the measurements as feedback to another capable node for processing and fusion, which may be a sensing fusion node.

Providing raw measurements as feedback, that are collected over a plurality of low-bandwidth frequency carriers, may result in a large amount of information overhead that may impede efficient utilization of a network, specifically in the feedback direction and may significantly reduce the spectral efficiency of the system. Moreover, it does necessarily provide coherent fusibility of these measurements, collected over a plurality of low-bandwidth frequency carriers, at sensing fusion nodes, thereby significantly reducing the high sensing resolution and/or accuracy gains that may be associated with a spectrum fusion process of these measurements.

Thus, methods for providing spectrally fusible sensing information feedback at a fusing node, where the sensing information are obtained by collecting sensing measurements over a plurality of low-bandwidth frequency carriers, are desired.

In general, aspects of the present disclosure may relate to operation with a sensing fusion node and a sensing measurements node for enabling low-overhead and spectrally fusible sensing information feedback at the sensing fusion node. The sensing information feedback may comprise of a plurality of processed multi-path channel measurements, collected over a plurality of low-bandwidth frequency carriers, being measured and processed at the sensing measurements node, a plurality of average power measurements of the plurality of the received sensing signals, collected at the sensing measurement node over a plurality of low-bandwidth frequency carriers, and a plurality of carrier phase measurements collected at the sensing measurement node over a plurality of a plurality of low-bandwidth frequency carriers. The sensing measurements node may be configured to collect these sets of measurements and process them to decrease the overhead associated with providing feedback of the processed measurements to the sensing fusion node. The sensing fusion node may be configured to coherently fuse the sensing information feedback, sent by the sensing measurements node, to increase the time/delay-resolution and/or accuracy of the sensing parameters related to the received sensing information feedback.

Aspects of the present application may relate to configuring a sensing measurements node to perform a plurality of multi-path channel measurements over a plurality of frequency carriers, to process and compress the plurality of multi-path channel measurements, according to processing and compression methods, and to feedback or report the plurality of the processed and compressed measurements to a sensing fusion node. Additionally, the sensing measurements node may be configured to perform a plurality of carrier phase measurements over a plurality of the frequency carriers and feedback or report these measurements to the sensing fusion node.

Aspects of the present disclosure relate to a joint design and configuration of the feedback and reporting methods for a plurality of multi-path channel measurements collected over a plurality of low-bandwidth frequency carriers. Measurements feedback methods may utilize correlation among the multi-path channel measurements to report the multi-path channel measurements obtained over one specific frequency carrier and report differential sensing information contained in the multi-path channel measurements taken over the remainder of the plurality of the frequency carriers, as compared to the measurements taken over the specific frequency carrier. The joint design and configuration of the feedback and reporting methods of a plurality of multi-path channel measurements collected over a plurality of low-bandwidth frequency carriers may reduce the overhead of feeding back and reporting the multi-path channel measurements, collected over a plurality of low-bandwidth frequency carriers, to the sensing fusion node.

Other aspects of the present disclosure may relate to configuring the sensing measurements node to transmit a plurality of sensing signals, to the sensing fusion node, after modulation with a plurality of processed and compressed multi-path channel measurements, collected over a plurality of low-bandwidth frequency carriers and before the transmission of the plurality of the later sensing signals to the sensing fusion node. These methods of joint measurements and measurements feedback and reporting may reduce the overhead of the measurements fusion process and obtaining the sensing parameters at the sensing fusion node.

Proper spectrum fusion of a plurality of multi-path channel measurements, collected over a plurality of the low-bandwidth frequency carriers, may require coherent processing of these measurements over time/delay and/or spectrum/frequency domains, depending on the utilized waveform, by compensating for the carrier phase offsets across the plurality of low-bandwidth frequency carriers that may be utilized in carrying sensing signals and measurements collected using the sensing signals. Compensating for the carrier phase offsets across the plurality of low-bandwidth frequency carriers may provide phase continuity among the multi-path channel measurements, thereby gaining high sensing resolution and/or accuracy in estimating the sensing parameters associated with multi-path channel measurements. Accordingly, aspects of the present disclosure may be related to carrier phase measurements, at the sensing measurements node and feedback and reporting methods of these measurements to the sensing fusion node. The carrier phase measurements and feedback and reporting methods are related to performing carrier phase measurements over a plurality of low-bandwidth frequency carriers and reporting or feeding back the relative phase offsets among the plurality of the low-bandwidth frequency carriers to the sensing fusion node.

One advantage of spectrum fusion measurements and feedback methods, representative of some aspects of the present disclosure, is providing viable solutions for obtaining low-overhead sensing information feedback/report, at a sensing fusion node, of a plurality of sensing measurements collected at a sensing measurements node over a plurality of low-bandwidth frequency carriers. This may provide obtaining high-resolution sensing services for low-end and/or low-capability sensing measurements nodes (e.g. drones) by offloading the spectrum fusion processing to a sensing fusion node (e.g. base station) through low-overhead sensing information feedback and reporting methods. Utilizing low-bandwidth sensing signals may expand high-resolution sensing capabilities of next wireless systems through increasing the number of transmitting (TX) and receiving (RX) sensing nodes/UEs potentially providing high-resolution sensing activities (providing measurements and/or sensing signals) by including low-end and/or low-capability UEs such as drones and Internet of Things (IoT) devices (e.g. low-end IoT devices).

The methods of spectrum fusion measurements and feedback representative of aspects of the present disclosure may also provide flexibility of required sensing patterns in terms of time and frequency resources allocations required for sensing measurements and sensing fusion nodes, participating in sensing procedures, which may enable opportunistic resource allocation. This, in turn, may address resource allocation issues in networks and provides freedom to prioritize sensing or communication methods based on the involved applications. For instance, in case of prioritizing communication, the network sensing node (e.g. base station) may spread allocated time-frequency resources over wide time and spectrum spans in a manner to reduce or eliminate interference with the allocated communication resources.

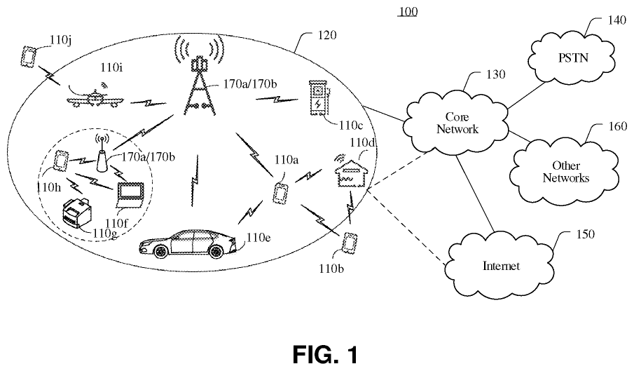

Referring to FIG. 1, as an illustrative example without limitation, a simplified schematic illustration of a communication system is provided. The communication system 100 comprises a radio access network 120. The radio access network 120 may be a next generation (e.g. sixth generation (6G) or later) radio access network, or a legacy (e.g. 5G, 4G, 3G or 2G) radio access network. One or more communication electronic devices (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

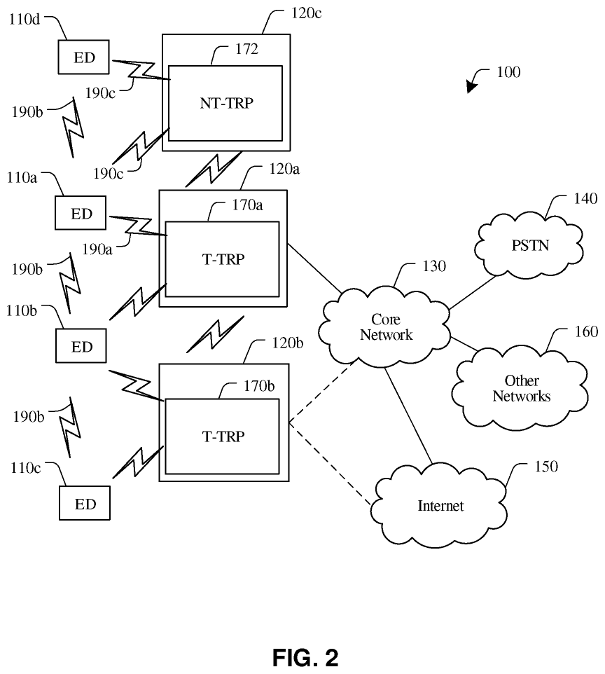

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast, groupcast, unicast, etc. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, etc.). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, nod (generically referred to as ED no), radio access networks (RANs) 120a, 120b, a non-terrestrial communication network 120c, a core network 130, a public switched telephone network (PSTN) 140, the Internet 150, and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED no may be alternatively or additionally configured to interface, access, or communicate with any T-TRP 170a,170b and NT-TRP 172, the Internet 150, the core network 130, the PSTN 140, the other networks 160, or any combination of the preceding. In some examples, ED 110a may communicate an uplink and/or downlink transmission over a terrestrial air interface 190a with T-TRP 170a. In some examples, the EDs 110a, 110b, 110c, and 110d may also communicate directly with one another via one or more sidelink air interfaces 190b. In some examples, ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA, also known as discrete Fourier transform spread OFDMA, DFT-s-OFDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANs 120a and 120b or EDs 110a 110b, and 110c or both, and (ii) other networks (such as the PSTN 140, the Internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the Internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), User Datagram Protocol (UDP). EDs 110a 110b, and 110c may be multimode devices capable of operation according to multiple radio access technologies, and incorporate multiple transceivers necessary to support such.

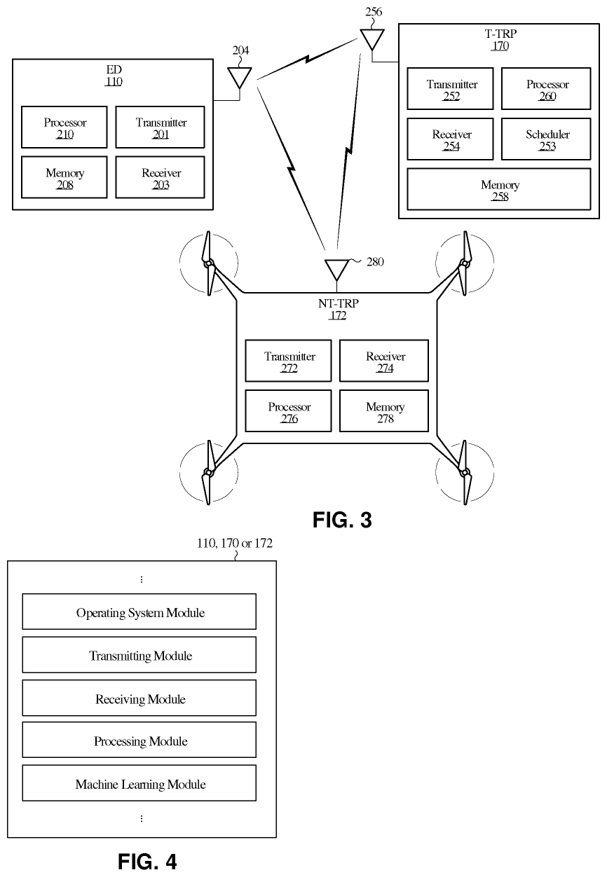

FIG. 3 illustrates another example of an ED 110 and a base station 170a, 170b and/or 170c. The ED 110 is used to connect persons, objects, machines, etc. The ED 110 may be widely used in various scenarios including, for example, cellular communications, device-to-device (D2D), vehicle to everything (V2X), peer-to-peer (P2P), machine-to-machine (M2M), machine-type communications (MTC), internet of things (IoT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, etc.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices (such as a watch, a pair of glasses, head mounted equipment, etc.), an industrial device, or an apparatus in (e.g. communication module, modem, or chip) or comprising the forgoing devices, among other possibilities. Future generation EDs 110 may be referred to using other terms. The base station 170a and 170b is a T-TRP and will hereafter be referred to as T-TRP 170. Also shown in FIG. 3, a NT-TRP will hereafter be referred to as NT-TRP 172. Each ED 110 connected to T-TRP 170 and/or NT-TRP 172 can be dynamically or semi-statically turned-on (i.e., established, activated, or enabled), turned-off (i.e., released, deactivated, or disabled) and/or configured in response to one of more of: connection availability and connection necessity.

The ED 110 includes a transmitter 201 and a receiver 203 coupled to one or more antennas 204. Only one antenna 204 is illustrated to avoid congestion in the drawing. One, some, or all of the antennas 204 may alternatively be panels. The transmitter 201 and the receiver 203 may be integrated, e.g. as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (e.g., a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the Internet 150 in FIG. 1). The input/output devices or interfaces permit interaction with a user or other devices in the network. Each input/output device or interface includes any suitable structure for providing information to or receiving information from a user, and/or for network interface communications. Suitable structures include, for example, a speaker, microphone, keypad, keyboard, display, touch screen, etc.

The ED 110 includes the processor 210 for performing operations including those operations related to preparing a transmission for uplink transmission to the NT-TRP 172 and/or the T-TRP 170; those operations related to processing downlink transmissions received from the NT-TRP 172 and/or the T-TRP 170; and those operations related to processing sidelink transmission to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (e.g. by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, e.g. beam angle information (BAI), received from the T-TRP 170. In some embodiments, the processor 210 may perform operations relating to network access (e.g. initial access) and/or downlink synchronization, such as operations relating to detecting a synchronization sequence, decoding and obtaining the system information, etc. In some embodiments, the processor 210 may perform channel estimation, e.g. using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201, and the processing components of the receiver 203 may each be implemented by the same or different one or more processors that are configured to execute instructions stored in a memory (e.g. in the memory 208). Alternatively, some or all of the processor 210, the processing components of the transmitter 201, and the processing components of the receiver 203 may each be implemented using dedicated circuitry, such as a programmed field-programmable gate array (FPGA), an application-specific integrated circuit (ASIC), or a hardware accelerator such as a graphics processing unit (GPU) or an artificial intelligence (AI) accelerator.

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (e.g. a communication module, a modem, or a chip) in the forgoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, e.g. through the use of coordinated multipoint transmissions.

The T-TRP 170 includes at least one transmitter 252 and at least one receiver 254 coupled to one or more antennas 256. Only one antenna 256 is illustrated to avoid congestion in the drawing. One, some, or all of the antennas 256 may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to the NT-TRP 172, and processing a transmission received over backhaul from the NT-TRP 172. Processing operations related to preparing a transmission for downlink or backhaul transmission may include operations such as encoding, modulating, precoding (e.g. multiple input multiple output (MIMO) precoding), transmit beamforming, and generating symbols for transmission. Processing operations related to processing received transmissions in the uplink or over backhaul may include operations such as receive beamforming, demodulating received symbols, and decoding received symbols. The processor 260 may also perform operations relating to network access (e.g. initial access) and/or downlink synchronization, such as generating the content of synchronization signal blocks (SSBs), generating the system information, etc. In some embodiments, the processor 260 also generates an indication of beam direction, e.g. BAI, which may be scheduled for transmission by a scheduler 253. The processor 260 performs other network-side processing operations described herein, such as determining the location of the ED 110, determining where to deploy the NT-TRP 172, etc. In some embodiments, the processor 260 may generate signaling, e.g. to configure one or more parameters of the ED 110 and/or one or more parameters of the NT-TRP 172. Any signaling generated by the processor 260 is sent by the transmitter 252. Note that “signaling”, as used herein, may alternatively be called control signaling. Signaling may be transmitted in a physical layer control channel, e.g. a physical downlink control channel (PDCCH), in which case the signaling may be known as dynamic signaling. Signaling transmitted in a downlink physical layer control channel may be known as Downlink Control Information (DCI). Signaling transmitted in an uplink physical layer control channel may be known as Uplink Control Information (UCI). Signaling transmitted in a sidelink physical layer control channel may be known as Sidelink Control Information (SCI). Signaling may be included in a higher-layer (e.g., higher than physical layer) packet transmitted in a physical layer data channel, e.g. in a physical downlink shared channel (PDSCH), in which case the signaling may be known as higher-layer signaling, static signaling, or semi-static signaling. Higher-layer signaling may also refer to Radio Resource Control (RRC) protocol signaling or Media Access Control—Control Element (MAC-CE) signaling.

The scheduler 253 may be coupled to the processor 260. The scheduler 253 may be included within or operated separately from the T-TRP 170. The scheduler 253 may schedule uplink, downlink, sidelink, and/or backhaul transmissions, including issuing scheduling grants and/or configuring scheduling-free (e.g., “configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252, and the processing components of the receiver 254 may each be implemented by the same or different one or more processors that are configured to execute instructions stored in a memory, e.g. in the memory 258. Alternatively, some or all of the processor 260, the scheduler 253, the processing components of the transmitter 252, and the processing components of the receiver 254 may be implemented using dedicated circuitry, such as a programmed FPGA, a hardware accelerator (e.g., a GPU or AI accelerator), or an ASIC.

Although the NT-TRP 172 is illustrated as a drone only as an example, the NT-TRP 172 may be implemented in any suitable non-terrestrial form, such as satellites and high altitude platforms, including international mobile telecommunication base stations and unmanned aerial vehicles, for example. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated to avoid congestion in the drawing. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (e.g. MIMO precoding), transmit beamforming, and generating symbols for transmission. Processing operations related to processing received transmissions in the uplink or over backhaul may include operations such as receive beamforming, demodulating received symbols, and decoding received symbols. In some embodiments, the processor 276 implements the transmit beamforming and/or receive beamforming based on beam direction information (e.g. BAI) received from the T-TRP 170. In some embodiments, the processor 276 may generate signaling, e.g. to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272, and the processing components of the receiver 274 may each be implemented by the same or different one or more processors that are configured to execute instructions stored in a memory, e.g. in the memory 278. Alternatively, some or all of the processor 276, the processing components of the transmitter 272, and the processing components of the receiver 274 may be implemented using dedicated circuitry, such as a programmed FPGA, a hardware accelerator (e.g., a GPU or AI accelerator), or an ASIC. In some embodiments, the NT-TRP 172 may actually be a plurality of NT-TRPs that are operating together to serve the ED 110, e.g. through coordinated multipoint transmissions.

The T-TRP 170, the NT-TRP 172, and/or the ED 110 may include other components, but these have been omitted for the sake of clarity.

One or more steps of the embodiment methods provided herein may be performed by corresponding units or modules, according to FIG. 4. FIG. 4 illustrates units or modules in a device, such as in the ED 110, in the T-TRP 170, or in the NT-TRP 172. For example, a signal may be transmitted or output by a transmitting unit or by a transmitting module. A signal may be received or input by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be a circuit such as an integrated circuit. Examples of an integrated circuit includes a programmed FPGA, a GPU, or an ASIC. For instance, one or more of the units or modules may be logical such as a logical function performed by a circuit, by a portion of an integrated circuit, or by software instructions executed by a processor. It will be appreciated that where the modules are implemented using software for execution by a processor for example, the modules may be retrieved by a processor, in whole or part as needed, individually or together for processing, in single or multiple instances, and that the modules themselves may include instructions for further deployment and instantiation.

While not shown, the transmitting module and the receiving module may be part of, or combined into, a transceiver module. A transceiver module may also be known as an interface module, or simply an interface, for inputting and outputting operations.

Additional details regarding the EDs 110, the T-TRP 170, and the NT-TRP 172 are known to those of skill in the art. As such, these details are omitted here.

According to some aspects of the present disclosure, there is provided a method of obtaining a fusible sensing feedback information, collected over a plurality of frequency carriers, such as at a sensing fusion node, the method comprising of transmitting, such as to a sensing measurements node, configuration information for a first processing function, a measurement fusion function, that enables the fusibility of the plurality of measurement vectors, collected from a plurality of sensing signals transmitted over a plurality of frequency carriers. The method may include transmitting, such as to the sensing measurement node, configuration information for a second processing function that compresses the plurality of measurement vectors, collected over the plurality of frequency carriers. The method may include transmitting, such as to the sensing measurements node, configuration information for allowing carrier phase measurements and reporting over the plurality of frequency carriers. The method may include transmitting, such as to the sensing measurements node, configuration information for indicating the type of the sensing information feedback method. The method may include transmitting, such as to the sensing measurements node, configuration information for feeding back the obtained plurality of measurements over the plurality of frequency carriers. The method may include transmitting, such as to the sensing fusion node, configuration information of sensing signals that are received at the sensing measurements node, over the plurality of frequency carriers. The method may include transmitting, to the sensing measurements node, a plurality of sensing signals over the plurality of frequency carriers. The method may include receiving, such as at the sensing fusion node, such as from the sensing measurements node, feedback information that are related to the plurality of measurements, collected over a plurality of frequency carriers, such as at the sensing fusion node, a plurality of sensing parameters, related to the sensing measurements node, by jointly processing, the plurality of carrier phase measurements and the plurality of the compressed sensing information collected over the plurality of frequency carriers.

In embodiments described herein, parameters may be used for different aspects of obtaining and generating feedback and may be generally referred to or categorized as first parameters (or a first set of parameters), second parameters (or a second set of parameters), etc. For example, first parameters may be used to refer to parameters used for a first purpose, such as performing measurements, while second parameters may be used to refer to parameters used for a second purpose, such as generating a signal comprising fusible measurements.

According to some aspects of the present disclosure, there is provided a method of facilitating obtaining sensing feedback information, collected over a plurality of frequency carriers, such as at a sensing fusion node, the method comprising of performing measurements, such as at the sensing measurements node, according to a predefined first processing function, a measurement fusion function, on a plurality of sensing signals, received over a plurality of frequency carriers, to obtain a plurality of measurement vectors. The method may include determining, such as at the sensing measurements node, a reference measurement vector according to a predefined criterion. The method may include establishing, such as at the sensing measurements node, a mathematical representation for each measurement vector, except the reference measurement vector, according to the predefined measurement fusion function, such that the mathematical representation of each measurement vector, except the reference vector, is a function of the reference vector itself and a certain deviation vector, associated with each measurement vector, and adjusting scalers. The method may include compressing, such as at the sensing measurements node, according to a predefined compression method, the reference measurement vector and a plurality of the deviation vectors, associated with the other measurement vectors, and quantizing a plurality of the adjusting scalers. The method may include transmitting, from the sensing measurements node, such as to the sensing fusion node, the compressed reference measurement vector, the plurality of the compressed deviation vectors and the quantized plurality of the adjusting scalers.

According to some aspects of the present disclosure, there is provided a method of facilitating obtaining sensing feedback information, collected over a plurality of frequency carriers, such as at a sensing fusion node, the method comprising of performing measurements, such as at a sensing measurements node, according to a predefined first processing function, a measurement fusion function, on a plurality of sensing signals, received over a plurality of frequency carriers, to obtain a plurality of measurement vectors. The method may include compressing, such as at the sensing measurements node, according to a predefined compression function, the plurality of the measurement vectors. The method may include transmitting, such as from the sensing measurements node, a plurality of sensing signals, such as to the fusing node, after analog modulation of, in part, which may primarily comprise a time component of, the plurality of sensing signals by the compressed measurement vectors.

According to some aspects of the present disclosure, there is provided a method of providing coherent fusion of sensing feedback information, such as at a fusing node, the method comprising performing, such as at a sensing measurements node, carrier phase measurements on a plurality of sensing signals received over a plurality of frequency carriers. The method may include determining, such as at the sensing measurements node, a reference carrier, according to specific criterion. The method may include reporting, such as by the sensing measurements node, such as to the fusing node, the phase differences between the average phase of the receive signals, such as at the sensing measurements node, on the resource elements that carry a sensing signal received over the reference carrier and the average phase of the received sensing signals, such as the sensing measurements node, on the resource elements that carry sensing signals received over other carriers.

For illustrative purposes, specific exemplary embodiments will now be discussed in greater detail in conjunction with the figures.

In some aspects of the present application, there are three main nodes or terminals which are involved in the sensing procedures, namely, sensing management function (SMF), sensing fusion node, sensing measurements node.

The SMF may be implemented as a physical network entity or a logical network entity. The SMF may be shown to coordinate sensing procedures representative of aspects of the present application. The logical network entity version of the SMF may, for example, be implemented, by itself or part of it, at the sensing fusion node. The main functions of the SMF may include managing time and frequency resources and configurations of sensing signals and sensing pattern. Functions of the SMF may also include sending sensing signals' configurations, sending details and configurations of the sensing fusion process and sending configurations and the type of the feedback or reporting of the sensing information. Functions of the SMF may also include receiving updates on the estimated sensing parameters with high-resolution and/or accuracy. measurement information from the sensing measurements node and preprocessing the measurement information and spectrally fuse them to obtain high-resolution sensing information and high-resolution channel parameters related to a certain group of the TX sensing nodes.

The sensing fusion node may be implemented as a network node or a terminal or UE with spectrum fusion capabilities. The main functions of the sensing fusion node may include receiving parts of configurations related to sensing signals and sensing information feedback/report and feedback type from the SMF. Functions of the sensing fusion node may include indicating spectrum fusion and processing capabilities to the SMF. Additionally, functions of the sensing fusion node may include transmitting a plurality of low-bandwidth sensing signals over a plurality of frequency carriers to the sensing measurements node. Functions of the sensing fusion node may include receiving a pluralities of sensing measurements including compressed multi-path channel, average received power, and carrier phase measurements, as sensing information feedback and reporting, that are associated with a plurality of sensing signals that are transmitted over a plurality of frequency carriers. Functions of the sensing fusion node may include processing and spectrally fusing a pluralities of multi-path channel, average received power, and carrier phase measurements from a plurality of frequency carriers to calculate high-resolution and/or accuracy sensing parameters. Duties of the sensing fusion node may include sending the estimated sensing parameters to the SMF.

A sensing measurements node may be implemented as a UE. The main functions of a sensing measurements node may include receiving parts of configurations related to sensing signals and sensing information feedback and reporting and feedback type from the SMF. Functions of a sensing measurements node may include indicating limited spectrum fusion and processing capabilities to the SMF. Additionally, functions of a sensing measurements node may include receiving a plurality of low-bandwidth sensing signals over a plurality of frequency carriers. Functions of a sensing measurements node may include performing pluralities of sensing measurements including multi-path channel, average received power, and carrier phase measurements, that are associated with a plurality of sensing signals that are transmitted over a plurality of frequency carriers. Functions of a sensing measurements node may include processing and compressing the measurements vectors according to a predefined type of feedback/report method and sending the obtained sensing information feedback/report to the sensing fusion node. Functions of a sensing measurements node may include sending a plurality of sensing signals sensing to the sensing fusion node after modulating them by the sensing information feedback.

Some aspects of the present application relate to providing low-overhead and spectrally-fusible sensing information feedback to a sensing fusion node for obtaining high-resolution and/or high-accuracy sensing parameters estimation at the sensing fusion node. One main component of the sensing information feedback is a plurality of compressed and processed multi-path channel measurements that are performed, at a sensing measurements node, over a plurality of frequency carriers. The sensing measurements node may obtain a plurality of measurements vectors corresponding to receiving a plurality of sensing signals over a plurality of frequency carriers. One method to obtain high-resolution and/or high-accuracy sensing parameters is to spectrally fuse and interpolate (in time or frequency domain if needed) these measurements vectors at the sensing measurements node and estimate associated sensing parameters and feedback them to the SMF. However, not all the sensing measurements nodes have the capabilities of fusing and interpolating a plurality of measurements collected over a plurality of frequency carriers thereby not being able to obtain. high-resolution and/or high-accuracy sensing parameters.

In case of the sensing measurements node does not have measurements fusing and interpolating capabilities, the sensing measurements node, in one approach, estimates the sensing parameters based on processing the measurements vectors individually which results in low-resolution and/or low accuracy estimates of the sensing parameters. In another approach, the sensing measurements node feeds back or reports the measurement vectors, as raw measurements vectors, i.e., with only simple and minimal signal processing such as quantization, to the sensing fusion node where the sensing fusion node fuses and interpolates them and obtains high-resolution and/or high-accuracy sensing parameters. However, this approach may result in a large amount of feedback overhead required to send the measurements vectors to the sensing fusion node, thereby throttling the communication/control channel from the sensing measurements node to the sensing fusion node and significantly reducing the spectral efficiency of the sensing system or network.

Some aspects of the present application relates to providing a plurality of low-overhead feedback multi-path channel measurements to a sensing fusion node wherein a plurality of multi-path channel measurements, are collected over a plurality of frequency carriers, jointly processed and jointly compressed at a sensing measurements node. Based on receiving a plurality of sensing signal over a plurality of frequency carriers, the sensing measurements node obtains a plurality of measurements vectors, i.e., y₁, . . . , y_{K}, where K is the number of frequency carriers (equivalently, sensing signals). Each measurements vector contains multi-path channel measurements that are associated to a frequency carrier with low-bandwidth. One way of obtaining the plurality of the measurements vectors, y₁, . . . , y_{K}, is by demodulating and equalizing the plurality of the received sensing signals utilizing the knowledge of the transmitted sensing signals at the sensing measurements node. The plurality of the measurements vectors are processed by measurements function [symbol] ( ) to produce a post-processing vectors r₁, . . . , r_{K}, where rₖ= [symbol] (yₖ). The measurements function [symbol] ( ) is indicated to the sensing measurements node before the sensing process, i.e., preconfiguring the sensing measurements node with [symbol] ( ). The measurement function may be defined to reduce the feedback overhead under the condition that their outputs are fusible at the sensing fusion node. It may also facilitate the joint compression of the post-processed vectors r₁, . . . , r_{K} by enabling the mathematical representations of r₁, . . . , r_{K} as functions of one another. This may induce overhead reduction in feeding back/reporting the sensing information to the sensing fusion node. Another benefits of utilizing a measurement function at the measurement sensing node is [symbol] ( ) may be used a transformation/projection function which projects the measurements vectors on sparse domains. This may also reduce the required feedback overhead. One example of the measurement function is by obtaining the post-processed vectors r₁, . . . , r_{K} based on performing IFFT/FFT transform (depending on the waveform of the sensing signals) of the measurements vectors y₁, . . . , y_{K}, i.e., [symbol] (yₖ)=Fyₖ, where F is the FFT matrix.

Utilizing the measurements function, the post-processed vectors, i.e., r₁, . . . , r_{K}, can be formulated as rₖ=αₖrₘ+γₖdₖ, ∀k, where dₖ is a vector that contains differential sensing information that rₖ provides compared to the sensing information contained in rₘ and aₖ and γₖ are the adjusting parameters. One choice of rₘ is to be the post-processed vector associated with the middle frequency carrier of the set of the frequency carriers (where the set of the frequency carriers are ordered in an ascending order). One reason for this choice is the measurements vector associated with the middle frequency carrier might have the highest correlation with the other measurements vectors. Another choice may be the post-processed vector associated with the first frequency carrier (where the set of the frequency carriers are ordered in an ascending order). However, the mathematical relationships between the post-processed vectors may be formulated in a progressive way, i.e., rₖ₊₁=aₖ₊₁rₖ+γₖ₊₁d_{k+1.}

One simple example of formulating rₖ, ∀k, as function of one another may be given based on analyzing an OFDM system over a two-path channel. Consider a full-band transmission of an OFDM signal x(t) over N subcarriers and for transmission time T, the transmitted signal may be expressed as:

$$x ( t ) = {\sum }_{n = 0}^{N - 1} {q}_{n} exp ( \frac{j 2 π n t}{T} ) , 0 \leq t \leq T \qquad ( 1 )$$

wherein {qₙ}denote the QAM sensing pilots' symbols to be transmitted and B denotes that full bandwidth N=BT.

Assuming a two-path wireless channel with impulse response h(t)=c₁ exp(−j2πτ)+c₂ exp(−j2π(τ+Δτ)), the full-band measurement vector (the full-band received vector after demodulation and equalization), i.e., y may be expressed by:

$$y = {\{ {c}_{1} {e}^{- \frac{j 2 π n τ}{T}} + {c}_{2} {e}^{- \frac{j 2 π n ( τ + Δ τ )}{T}} \}}_{n = 0}^{N - 1} \qquad ( 2 )$$

In the case of sub-band processing (the proposed framework), access is only to a subset of the whole samples of y. For instance, let us assume the first measurement is at sub-band [symbol] ₁ covering frequencies of f₁:f₁+B₁ and the second measurement is at sub-band [symbol] ₂ covering frequencies of f₂:f₂+B₂, then, the samples of the first measurement correspond to n₁:n₁+N₁−1 and the samples of the second measurement correspond to n₂:n₂+N₂−1 wherein

$${n}_{1} = ⌊ \frac{{f}_{1} N}{B} ⌋ , {n}_{2} = ⌊ \frac{{f}_{2} N}{B} ⌋ , {N}_{1} = ⌊ \frac{{B}_{1} N}{B} ⌋ , {N}_{2} = ⌊ \frac{{B}_{2} N}{B} ⌋ .$$

### Then:

$${y}_{1} = \\ {\{ {c}_{1} {e}^{- \frac{j 2 π n τ}{T}} + {c}_{2} {e}^{- \frac{j 2 π n ( τ + Δ τ )}{T}} \}}_{n = {n}_{1}}^{{N}_{1} - 1} = {\{ {e}^{- \frac{j 2 π n τ}{T}} + ( {c}_{1} + {c}_{2} {e}^{- \frac{j 2 π n Δ τ}{T}} ) \}}_{n = {n}_{1}}^{{n}_{1} + {N}_{1} - 1} \qquad ( 3 )$$

$${y}_{2} = {\{ {c}_{1} {e}^{- \frac{j 2 π n τ}{T}} + {c}_{2} {e}^{- \frac{j 2 π n ( τ + Δ τ )}{T}} \}}_{n = {n}_{2}}^{{N}_{2} - 1} = {\{ {e}^{- \frac{j 2 π n τ}{T}} + ( {c}_{1} + {c}_{2} {e}^{- \frac{j 2 π n Δ τ}{T}} ) \}}_{n = {n}_{2}}^{{n}_{2} + {N}_{2} - 1} \qquad ( 4 )$$

To establish the relationships between the post-processing vectors rₖ, we use IFFT as p( )

IFFT terms may be further calculated as:

$${r}_{1} = IFFT ( {y}_{1} ) = {c}_{1} IFFT ( {\{ {e}^{- \frac{j 2 π n τ}{T}} \}}_{n = {n}_{1}}^{{n}_{1} + {N}_{1} - 1} ) + {c}_{2} IFFT ( {\{ {e}^{- \frac{j 2 π n ( τ + Δ τ )}{T}} \}}_{n = {n}_{1}}^{{n}_{1} + {N}_{1} - 1} ) = {c}_{1} {e}^{- \frac{j 2 π {n}_{1} τ}{T}} IFFT ( {\{ {e}^{- \frac{j 2 π n τ}{T}} \}}_{n = 0}^{{N}_{1} - 1} ) + {c}_{2} {e}^{- \frac{j 2 π {n}_{1} ( τ + Δ τ )}{T}} IFFT ( {\{ {e}^{- \frac{j 2 π n ( τ + Δ τ )}{T}} \}}_{n = 0}^{{N}_{1} - 1} ) \\ And similarly : \\ {r}_{2} = IFFT ( {y}_{2} ) = {c}_{1} {e}^{- \frac{j 2 π {n}_{2} τ}{T}} IFFT ( {\{ {e}^{- \frac{j 2 π n τ}{T}} \}}_{n = 0}^{{N}_{2} - 1} ) + {c}_{2} {e}^{- \frac{j 2 π {n}_{2} ( τ + Δ τ )}{T}} IFFT ( {\{ {e}^{- \frac{j 2 π n ( τ + Δ τ )}{T}} \}}_{n = 0}^{{N}_{2} - 1} )$$

Now, provided that N₁=N₂ and denoting

$${w}_{1} = IFFT ( {\{ {e}^{- \frac{j 2 π n τ}{T}} \}}_{n = 0}^{{N}_{1} - 1} ) and {w}_{2} = IFFT ( {\{ {e}^{- \frac{j 2 π n ( τ + Δ τ )}{T}} \}}_{n = 0}^{{N}_{1} - 1} ) ,$$

the relation between r₁ and r₂ can be expressed as:

$${r}_{1} = {c}_{1} {e}^{- \frac{j 2 π {n}_{1} τ}{T}} {w}_{1} + {c}_{2} {e}^{- \frac{j 2 π {n}_{1} ( τ + Δ τ )}{T}} {w}_{2} \qquad ( 6 )$$

$${r}_{2} = {c}_{1} {e}^{- \frac{j 2 π {n}_{2} τ}{T}} {w}_{1} + {c}_{2} {e}^{- \frac{j 2 π {n}_{1} ( τ + Δ τ )}{T}} {w}_{2} , \qquad ( 7 )$$

Thus, the post processing vectors rₖ∀k, are complex linear combinations of the same bases wₗ∀l.

To identify the differential information contained in r₂ compared to r₁, r₂ may be represented in terms of r₁ and the differential information term as:

$$\begin{matrix}{r}_{2} = {e}^{- \frac{j 2 π ( {n}_{2} - {n}_{1} ) τ}{T}} [ {c}_{1} {e}^{- \frac{j 2 π {n}_{1} τ}{T}} {w}_{1} + {c}_{2} {e}^{- \frac{j 2 π {n}_{1} ( τ + Δ τ )}{T}} {w}_{2} ] + \\ {c}_{2} {e}^{- \frac{j 2 π {n}_{2} τ}{T}} ( {e}^{- \frac{j 2 π {n}_{2} Δ τ}{T}} - {e}^{- \frac{j 2 π {n}_{1} Δ τ}{T}} ) {w}_{2} \\ = {e}^{- \frac{j 2 π ( {n}_{2} - {n}_{1} ) τ}{T}} {r}_{1} + {c}_{2} {e}^{- \frac{j 2 π {n}_{2} τ}{T}} ( {e}^{- \frac{j 2 π {n}_{2} Δ τ}{T}} - {e}^{- \frac{j 2 π {n}_{1} Δ τ}{T}} ) {w}_{2} \\ = {e}^{- \frac{j 2 π ( {n}_{2} - {n}_{1} ) τ}{T}} {r}_{1} + 2 {c}_{2} {e}^{- \frac{j 2 π {n}_{2} τ}{T}} {e}^{- \frac{j 2 π ( \frac{{n}_{1} + {n}_{2}}{2} ) Δ τ}{T}} sin ( \frac{π ( {n}_{1} - {n}_{2} ) Δ τ}{T} ) {w}_{2} \\ = {e}^{- \frac{j 2 π ( {n}_{2} - {n}_{1} ) τ}{T}} [ {r}_{1} + 2 j {c}_{2} {e}^{- \frac{j 2 π {n}_{1} τ}{T}} {e}^{- \frac{j 2 π ( \frac{{n}_{1} + {n}_{2}}{2} ) Δ τ}{T}} sin ( \frac{π ( {n}_{1} - {n}_{2} ) Δ τ}{T} ) {w}_{2} ]\end{matrix}$$

The key point is that the terms

$${e}^{- \frac{j 2 π ( {n}_{2} - {n}_{1} ) τ}{T}} , {e}^{- \frac{j 2 π {n}_{1} τ}{T}} , {e}^{- \frac{j 2 π ( \frac{{n}_{1} - {n}_{1}}{2} ) Δ τ}{T}} , sin ( \frac{π ( {n}_{1} - {n}_{2} ) Δ τ}{T} )$$

are constant for all samples of the vector r₂. Defining

$$ϕ ( τ ) = \frac{2 π ( {n}_{2} - {n}_{1} ) τ}{T} and \\ {β}_{2} = 2 {c}_{2} {e}^{- \frac{j 2 π {n}_{1} τ}{T}} {e}^{- \frac{j 2 π ( \frac{{n}_{1} + {n}_{2}}{2} ) Δ τ}{T}} sin ( \frac{π ( {n}_{1} - {n}_{2} ) Δ τ}{T} ) ,$$

the above equation may be expressed as:

$${r}_{2} = {e}^{- j ϕ ( τ )} [ {r}_{1} + {β}_{2} {w}_{2} ]$$

Random phase offsets may be added to each sub-band measurement, denoted by φ_{off}, which can be combined by φ(τ) to give φ. This φ value can be estimated and compensated, which provides: \tilde{r}₂=r₁+β₂w₂.

On the other hand,

$${w}_{2} = IFFT ( {\{ {e}^{- \frac{j 2 π n ( τ + Δ τ )}{T}} \}}_{n = 0}^{{N}_{1} - 1} )$$

is basically a sinc(.) function centered at the true delay τ+Δτ and the sidelobe depends on the number of samples (N₁) and scaled by β₂. β₂ contains a term sin

$$( \frac{π ( {n}_{1} - {n}_{2} ) Δ τ}{T} )$$

which controls the amplitude of the additional term, depending on the distance between the sub-bands (n₂−n₁) as well as the Δτ.

Thus, referenced to the aforementioned generalized procedure, the first processing function [symbol] ( ) is given by N-point IFFT function, the vectors to be compressed and feed-back to the fusing node are, r₁ and β₂w₂ and a scaler value φ. Here, the differential information vector d₂=β₂w₂, α₂=1 and γ₂=1. In a more generalized case, dₖ might be represented as a summation of multiple bases and α₂ and γ2 have non-unit values.

Another simple example of formulating rₖ, ∀k, as function of one another may be given based on analyzing a chirp-based sensing system over a two-path channel. Using simple mathematical manipulations, the same formulations obtained for the OFDM-based sensing system can be obtained for the chirp-based sensing system. To illustrate this, considering a two-path channel where the transmitted signal is a single chirp signal with chirp rate

$$α = \frac{B}{T}$$

covering frequencies from [0: B] over the time duration of T, the received signal at the sensing measurement node may be expressed as:

$$y ( t ) = {c}_{1} exp ( j {πα ( t - τ )}^{2} ) + {c}_{1} exp ( j {πα ( t - τ - Δ τ )}^{2} ) = exp ( j πα {t}^{2} ) [ {c}_{1} exp ( j {πατ}^{2} ) exp ( - j 2 π α τ t ) + {c}_{2} exp ( j {πα ( τ + Δ τ )}^{2} ) exp ( - j 2 π α ( τ + Δ τ ) t ) ] = exp ( j πα {t}^{2} ) [ {c}_{1}^{′} exp ( - j 2 π α τ t ) + {c}_{2}^{′} exp ( - j 2 π α ( τ + Δ τ ) t ) ]$$

Which is true for τ+Δτ−t_{cp}≤t≤T. If t_{cp}>d_{s,max}, i.e. maximum delay spread of the channel, then the receiver may sample the received signal between o and T. Over this period of time, multiplying the received signal by exp(jπαt²):

$$s ( t ) = {c}_{1}^{′} exp ( - j 2 π α τ t ) + {c}_{2}^{′} exp ( - j 2 π α ( τ + Δ τ ) t )$$

Sampling s(t) at the Nyquist rate, i.e. at

$${t}_{n} = \frac{n}{B} , n = 0 , … , N - 1 :$$

$$s = {\{ {c}_{1}^{′} exp ( - \frac{j 2 π α τ n}{B} ) + {c}_{1}^{′} exp ( - \frac{j 2 π α ( τ + Δ τ ) n}{B} ) \}}_{n = 0}^{N - 1} = {\{ {c}_{1}^{′} {e}^{- \frac{j 2 π n τ}{T}} + {c}_{1}^{′} {e}^{- \frac{j 2 π n ( τ + Δτ )}{T}} \}}_{n = 0}^{N - 1}$$

Which exactly matches with (2), except for the coefficients which are related through

$${c}_{1}^{′} = {c}_{1} exp ( j {πατ}^{2} ) and {c}_{2}^{′} = {c}_{2} exp ( j {πα ( τ + Δ τ )}^{2} ) ,$$

i.e., same amplitude with some phase rotations. Thus, the detection formulation or OFDM and chirp are exactly the same when Nyquist sampling is applied. However, the key advantage of the chirp is that it can sample the signal with much lower rate and still no information is lost since the sampling rate should be higher than α(z+Δτ) which is much smaller than B.

Thus, having the post-processed vectors formulated as rₖ=αₖrₘ+γₖdₖ, ∀k, instead of compressing rₖ∀k, as aspect of the present invention related to compressing rₘ, i.e., the post-processed vector associated with the reference frequency carrier and compressing dₖ∀k. This may be performed based on preconfiguring the sensing measurements node to utilize a compression function, i.e., [symbol] ( ), to compress rₘ, and dₖ for all k except k=m and produce z₁, . . . , z_{K}, such that zₖ= [symbol] (dₖ) except for k=m, zₘ= [symbol] (rₘ). Then, the sensing measurements node feeds back or reports z₁, . . . , z_{K} along with aₖ and yₖ to the sensing fusing node. Compressing dₖ, for all k, has much less feedback overhead compared to compressing rₖ, for all k, themselves since dₖ, for all k, from information theoretic perspective, contain less sensing information where they contain only the differential sensing information while rₖ, for all k, have much redundant sensing information due to the high correlation among them. The details of the compression function [symbol] ( ) may be included in the configuration messages sent to the sensing measurements node by the SMF. One implementation of the compression function [symbol] ( ) is by rendering z includes samples of

$$\frac{r}{{d}_{k}} ,$$

based on uniform sampling with pre-configured sampling frequency. Another implementation is based on non-uniform sampling with pre-configured sampling frequency. An example would be zₘ(l)=rₘ(n), or, zₖ(l)=dₖ(n) such that |r(n)|=A−nt, or, wherein A denotes the maximum peal amplitude, t defines a configured step parameter. This example corresponds to the case that the samples obtained based on the amplitude thresholds. The amplitude values can be expressed in regular or in dB scale. Moreover, the configuration parameters may include cut-off thresholds r_{cut} that controls the compression process.

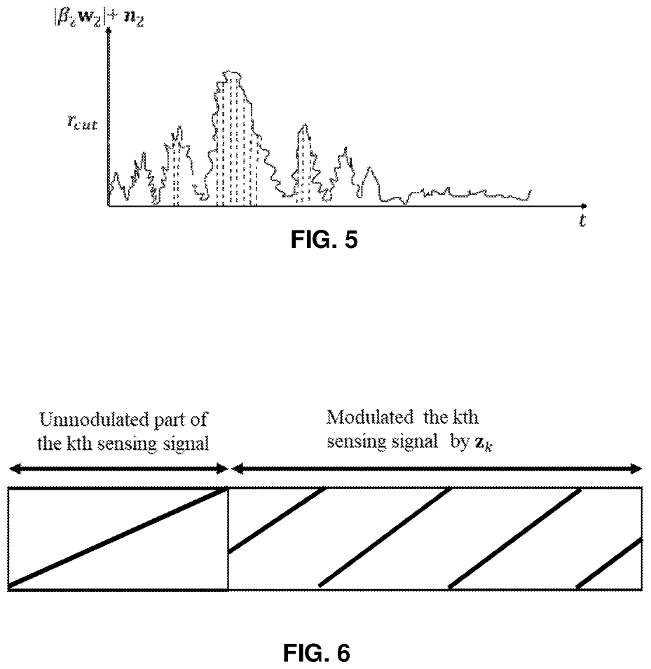

Referring to the aforementioned two-path channel example, the quantization of |β₂w₂|, involve quantizing a noisy version (due to the AWGN) of a weighted |sinc| as illustrated in FIG. 5:

Due to the knowledge of the underlying shape of |β₂w₂|, only some parts of it can be sampled and quantized finely while the rest of it is coarsely quantized. Thus, the compression function for this example, in reference to the generalized differential feedback procedure, i.e., the compression function here, [symbol] , is the compounding effect of absolute function, thresholding, sampling and quantization. In this way, the feedback information of this example is z₁= [symbol] (r₁), z₂= [symbol] (|β₂w₂|)+ [symbol] (∠ [symbol] (β [symbol] ₂w₂)) and φ.

Some aspects of the present application relates to providing a plurality of low-overhead feedback multi-path channel measurements along with a second plurality of sensing signals to a sensing fusion node wherein a plurality of multi-path channel measurements, are collected from a first plurality of sensing signals over a plurality of frequency carriers, and processed for analog modulation of, in part, the second plurality of the sensing signals at a sensing measurements node. In this multi-path channel measurements feedback method, a sensing fusion node transmits a first plurality of sensing signals over a plurality of frequency carriers. A sensing measurements node calculates zₖ, for all the frequency carriers, based on the aforementioned methods. Then, the sensing measurements node utilizes zₖ, for all k, for analog modulation of a second polarity of sensing signals, where the second set of the sensing signals are transmitted from the sensing measurements node to the sensing fusion node. For all values of k, zₖ modulates part of the sensing signal that are associated to the kth frequency carriers of the second set of the sensing signal as shown as in FIG. 6

The unmodulated kth sensing signal may be utilized at the sensing fusion node to perform a second plurality of multi-path channel measurements that would be ultimately spectrally fused with the first plurality the multi-path channel measurements, captured in zₖ, for all values of k, and embedded in the second part (modulated part) of the kth sensing signal. The second plurality of the sensing signals may be transmitted over a different plurality of frequency carriers from the first plurality of the frequency carriers in order to allow for spectrally-fuse the multi-path measurements associated with the first plurality of the frequency carriers and the multi-path measurements associated with the second plurality of the frequency carriers at the sensing fusion node. For the channel reciprocity condition between the sensing measurements and fusion nodes in both directions, and thereby the associated sensing parameters, the receiver structure for detecting the second plurality of the sensing signals may be implemented by firstly, the unmodulated part of the kth sensing signal of the second plurality of the sensing signals is processed to obtain a second measurement vector

$${r}_{k}^{′} ,$$

for all k. Then, the modulated part of kth sensing signal of the second plurality of the sensing signals, modulated by zₖ, is used to obtain zₖ based on the knowledge of

$${r}_{k}^{′} .$$

In some embodiments of the present disclosure, linear frequency modulated (LFM), a.k.a. chirp, signals can be used to modulate the multi-path channel measurements. In this case, the unmodulated signal may be expressed as:

$${x}_{unmod} ( t ) = exp ( j 2 π {f}_{0} t + j π α {t}^{2} ) ,$$

Wherein f₀ denotes the initial frequency and α denotes the chirp slope. Both these parameters are the configuration parameters and can be configured for the sensing measurement node. The modulated signal may be expressed as:

$${x}_{m o d} ( t ) = {x}_{u n m o d} ( t ) \cdot z ( t )$$

Wherein z(t) is a function whose time-domain samples are

$${\{ {z}_{k , l} \}}_{{k = 1 : K}_{l = 1 : L}} ,$$

in which z_{k,l} is the lth element in the vector zₖ and L is the length of the vectors zₖ, k=1, . . . , K.

At the sensing fusion node, first a rough estimate of the channel multi-path components may be obtained from the unmodulated part of the sensing signal x_{unmod}(t), and then, this estimate may be used to equalize the modulated part of the signal x_{mod} (t) in order to estimate the samples

$${\{ {z}_{k , l} \}}_{{k = 1 : K}_{l = 1 : L}} .$$

A second main component of the sensing information feedback, that renders the sensing information feedback, collected over a plurality of frequency carriers is spectrally-fusible at the sensing fusion node, is a plurality of carrier phase measurements, at a sensing measurement node, and a plurality of carrier phase feedback associated to the plurality of carrier phase measurements, at a sensing fusion node. Each multi-path channel measurements, either at the sensing measurements/fusion node belong to a different frequency carrier experiences a different phase. Thus, there is a phase drift that occurs for the different sensing carriers due to hardware impairments and limitations. To guarantee that the multi-path channel measurements, collected over a plurality of frequency carriers, are added coherently at the sensing fusion node, the plurality of the phase shifts/drifts associated with the plurality of frequency carriers are measured at the sensing measurements node and are feed back to the sensing fusion measurements node. One way of implement this may be based on using phase tracking reference signals that are associated with each frequency carrier (or equivalently associated with each sensing signals), such as carrier fusion phase tracking reference (CF-PTRS). These CF-PTRS may be accompanying the sensing signals themselves or based on specific carrier fusion phase tracking reference. The sensing measurements node may feedback/report the difference of the average phase of the receive signals on the resource elements that carry the sensing signal received over a reference frequency carrier (e.g., zₘ) and the average phase of the receive signals on the resource elements that carry the sensing signal received over another carrier. This might be called received signal relative phase (RSRPh) measurement. The reported RSRPh may be quantized according to a predefined phase quantization codebooks and feedback to the sensing fusion node. In some embodiments, the reported RSRPh may be modulated in an analog fashion and transmitted to the sensing fusion node.

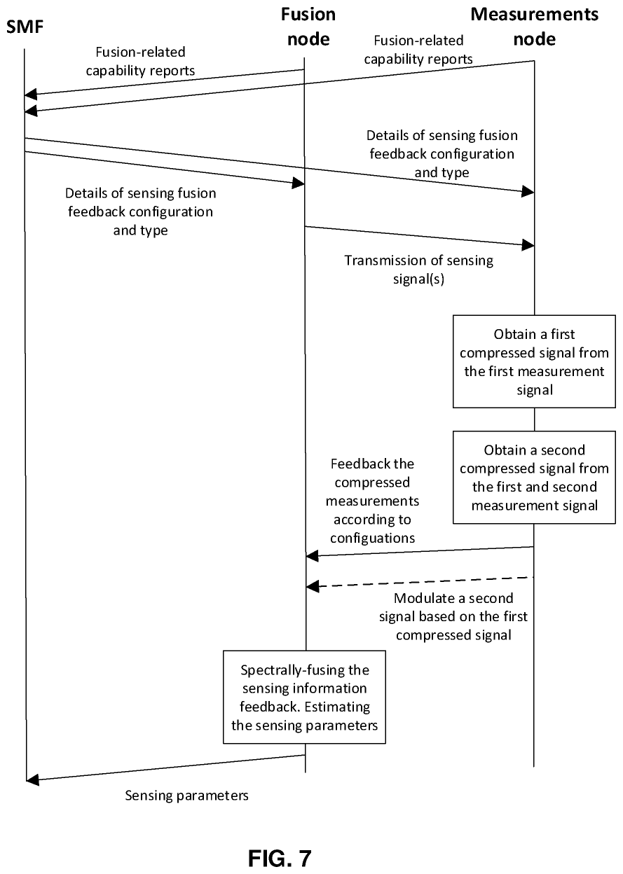

Referring to FIG. 7, in a signal flow diagram, a flow of information, sensing signals and feedback associated with aspects of the present application.

The signalling procedure may start as the SMF, optionally, recalls some sensing-fusion capability reports from a sensing measurements and fusion nodes. The capability reports may include the capability of transmitting/receiving over multiple bandwidth parts and frequency carriers, maximum supported bandwidth, dynamic ranges, capabilities of performing time/frequency and phase measurements, and fusion processing capabilities. Then, the SMF transmits to the sensing measurements node and the sensing fusion node configurations and resource allocation for the downlink (from the sensing fusion node to the sensing measurements node) sensing signals (and if necessarily, the uplink-from the sensing measurements node to the sensing fusion node-sensing signals). Note that if the SMF is a logical entity, it may be considered inaccurate to indicate that the SMF “transmits/receives” the configurations. Instead, the configurations may be transmitted by a physical entity, such as the sensing fusion node or alternatively, another network node like a TRP. Further notably, the signaling of configuration parameters to the sensing fusion node can be carried out through Xn signaling, since configuration transmission may be considered to be “backhaul signaling,” which may be distinct from access signaling. Part of the configuration parameters may be related to the type of the sensing information feedback method, either a differential feedback method or modulating feedback method. The transmitting of the sensing configuration parameters may be accomplished using control signalling, e.g., RRC or MAC-CE. According to the configuration parameters indicated by the SMF, the sensing fusion node transmits a plurality of sensing signals over a plurality of frequency carriers.

Subsequently, the sensing measurements node performs a plurality of multipath channel measurements, applies measurement and compression functions to produce zₖ for all values of k, and performs a plurality of carrier phase measurements. Then, the sensing measurements node either directly feedback zₖ for all values of k along with the carrier phase measurements to the sensing fusion node or it embeds them into a second set of sensing signals. Based on the reception on the plurality of the multi-path channel measurements and the carrier phase measurements, the sensing fusion node coherently fuse the plurality of the multi-path channel measurements to obtain high-resolution sensing parameters where their finally sent to the SMF.

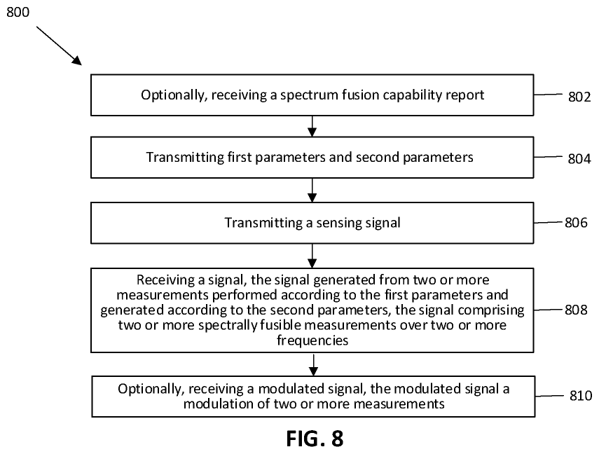

FIG. 8 is a flowchart showing the steps of a method 800, according to some embodiments of the present disclosure. The method 800 begins with, optionally, receiving a spectrum fusion capability report (step 802). At step 804, the method comprises transmitting first parameters and second parameters. At step 806, the method comprises transmitting the sensing signal. At step 808, the method comprises receiving a signal, the signal generated from two or more measurements performed according to the first parameters and generated according to the second parameters, the signal comprising two or more spectrally fusible measurements over two or more frequencies. At step 810, the method comprises, optionally, receiving a modulated signal, the modulated signal a modulation of two or more measurements.

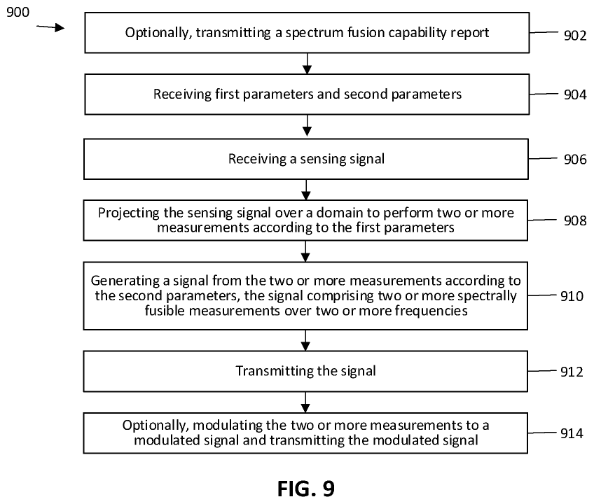

FIG. 9 is a flowchart showing the steps of a method 900, according to some embodiments of the present disclosure. The method 900 begins with, optionally, transmitting a spectrum fusion capability report (step 902). At step 904, the method comprises receiving first parameters and second parameters. At step 906, the method comprises receiving a sensing signal. At step 908, the method comprises projecting the sensing signal over a domain to perform two or more measurements according to the first parameters. At step 910, the method comprises generating a signal from the two or more measurements according to the second parameters, the signal comprising two or more spectrally fusible measurements over two or more frequencies. At step 912, the method comprises transmitting the signal. At step 914, the method comprises, optionally, modulating the two or more measurements to a modulated signal and transmitting the modulated signal

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

Features disclosed herein in the context of any particular embodiments may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

What is claimed is:

1. A method comprising:
receiving first parameters and second parameters;
receiving a sensing signal;
projecting the sensing signal over a domain to perform two or more measurements according to the first parameters;
generating a signal from the two or more measurements according to the second parameters, the signal comprising two or more spectrally fusible measurements over two or more frequencies; and
transmitting the signal.

2. The method of claim 1, further comprising transmitting a spectrum fusion capability report.

3. The method of claim 1, wherein the two or more measurements are embedded in the signal.

4. The method of claim 1, wherein the two or more measurements comprise at least one of measurements of average power for different frequency bandwidths or spectrum fusion carrier phase measurements.

5. The method of claim 1, wherein the second parameters comprise at least one of:
parameters for uniform sampling using a configured sampling frequency,
parameters for non-uniform sampling with a configured sampling frequency,
parameters for measuring amplitude of samples,
parameters for measuring real and imaginary components of samples,
parameters for pre-configured quantization, or
cut-off thresholds.

6. A method comprising:
transmitting first parameters and second parameters;
transmitting a sensing signal; and
receiving a signal, the signal generated from two or more measurements performed according to the first parameters and generated according to the second parameters, the signal comprising two or more spectrally fusible measurements over two or more frequencies.

7. The method of claim 6, further comprising receiving a spectrum fusion capability report.

8. The method of claim 6, wherein the two or more spectrally fusible measurements are embedded in the signal.

9. The method of claim 6, wherein the two or more measurements comprise at least one of measurements of average power for different frequency bandwidths or spectrum fusion carrier phase measurements.

10. The method of claim 6, wherein the second parameters comprise at least one of:
parameters for uniform sampling using a configured sampling frequency,
parameters for non-uniform sampling using a configured sampling frequency,
parameters for measuring amplitude of samples,
parameters for measuring real and imaginary components of samples,
parameters for pre-configured quantization, or
cut-off thresholds.

11. An apparatus comprising:
at least one processor; and
memory coupled to the at least one processor and storing instructions that, when executed by the at least one processor, cause the apparatus to perform operations including:
receiving first parameters and second parameters;
receiving a sensing signal;
projecting the sensing signal over a domain to perform two or more measurements according to the first parameters;
generating a signal from the two or more measurements according to the second parameters, the signal comprising two or more spectrally fusible measurements over two or more frequencies; and
transmitting the signal.

12. The apparatus of claim 11, wherein the operations further comprise transmitting a spectrum fusion capability report.

13. The apparatus of claim 11, wherein the two or more measurements are embedded in the signal.

14. The apparatus of claim 11, wherein the two or more measurements comprise at least one of measurements of average power for different frequency bandwidths or spectrum fusion carrier phase measurements.

15. The apparatus of claim 11, wherein the second parameters comprise at least one of:
parameters for uniform sampling using a configured sampling frequency,
parameters for non-uniform sampling with a configured sampling frequency,
parameters for measuring amplitude of samples,
parameters for measuring real and imaginary components of samples,
parameters for pre-configured quantization, or
cut-off thresholds.

16. An apparatus comprising:
at least one processor; and
memory coupled to the at least one processor and storing instructions that, when executed by the at least one processor, cause the apparatus to perform operations including:
transmitting first parameters and second parameters;
transmitting a sensing signal; and
receiving a signal, the signal generated from two or more measurements performed according to the first parameters and generated according to the second parameters, the signal comprising two or more spectrally fusible measurements over two or more frequencies.

17. The apparatus of claim 16, wherein the operations further comprise receiving a spectrum fusion capability report.

18. The apparatus of claim 16, wherein the two or more spectrally fusible measurements are embedded in the signal.

19. The apparatus of claim 16, wherein the two or more measurements comprise at least one of measurements of average power for different frequency bandwidths or spectrum fusion carrier phase measurements.

20. The apparatus of claim 16, wherein the second parameters comprise at least one of:
parameters for uniform sampling using a configured sampling frequency,
parameters for non-uniform sampling using a configured sampling frequency,
parameters for measuring amplitude of samples,
parameters for measuring real and imaginary components of samples,
parameters for pre-configured quantization, or
cut-off thresholds.
